(19) United States
(12) Patent Application Publication
(10) Pub. No.: US 2026/0237420 A1
(43) Pub. Date: Aug. 13, 2026

(54) DISCHARGE CIRCUIT, A CONTROL CIRCUIT AND A CONTROL METHOD THEREOF, A MEMORY AND A MEMORY SYSTEM

(71) Applicant: YANGTZE MEMORY TECHNOLOGIES CO., LTD., Wuhan (CN)

(72) Inventors: Leon LI, Wuhan (CN); Xiaoxiang AN, Wuhan (CN)

(21) Appl. No.: 19/236,486

(22) Filed: Jun. 12, 2025

(30) Foreign Application Priority Data
Feb. 8, 2025 (CN) 2025101421434

(51) Int. Cl. G11C 11/4074; G11C 5/14; G11C 11/408

(52) U.S. Cl. CPC G11C 11/4074; G11C 5/145; G11C 11/4085

(57) ABSTRACT

A control circuit of a memory includes a discharging end, a clamping unit, a first switching unit and a power supply branch, wherein the clamping unit is coupled with a word line of the memory, the first switching unit is coupled between the clamping unit and the discharging end and is configured to be in an on state from a first time to a second time, so that the word line is connected with the discharging end and a voltage of the word line is discharged from a first voltage to a target voltage; and the power supply branch is coupled with the word line and is configured to provide a second voltage to the word line after the second time, wherein the target voltage is less than or equal to the second voltage.

### CROSS-REFERENCE TO RELATED APPLICATIONS

The present disclosure claims priority to Chinese Patent Application No. 2025101421434, which was filed February 8, 2025, and is hereby incorporated herein by reference in its entirety.

### TECHNICAL FIELD

The present disclosure relates to the technical field of semiconductor, and more particularly, to a control circuit of a memory, a memory, a memory system, a control method of a memory, and a discharge circuit of a memory.

### BACKGROUND

The voltages required by the word lines may be different during different operations successively performed by the memory. For example, the voltage required by the word line during the previous operation is greater than the voltage of the word line during the next operation.

### SUMMARY

According to a first aspect, some examples of the present disclosure provide a control circuit of a memory. The control circuit of the memory comprises a discharging end, a clamping unit, a first switching unit and a power supply branch, wherein the clamping unit is coupled with a word line of the memory, the first switching unit is coupled between the clamping unit and the discharging end and is configured to be in an on state from a first time to a second time, so that the word line is connected with the discharging end, and a voltage of the word line is discharged from a first voltage to a target voltage; and the power supply branch is coupled with the word line and is configured to provide a second voltage to the word line after the second time, wherein the target voltage is less than or equal to the second voltage.

In an example implementation, the clamping unit includes a diode-connected MOS transistor, and a drain of the diode-connected MOS transistor is coupled with a gate of the diode-connected MOS transistor.

In an example implementation, the diode-connected MOS transistor is an NMOS transistor or a PMOS transistor.

In an example implementation, the voltage of the discharging end is less than or equal to the difference between the second voltage and a threshold voltage of the diode-connected MOS transistor.

In an example implementation, the clamping unit includes at least one of a diode or a resistor.

In an example implementation, the first switching unit is further configured to, in response to a controlled end of the first switching unit receiving a first control signal, be in the on state from the first time to the second time, and be in an off state before the first time and after the second time.

In an example implementation, the first switching unit includes a first transistor, wherein a first electrode of the first transistor is coupled with the clamping unit, a second electrode of the first transistor is coupled with the discharging end, and a control end of the first transistor is configured to receive the first control signal.

In an example implementation, the control circuit further includes a protection transistor coupled between the clamping unit and the first transistor, wherein the protection transistor performs overvoltage protection on the first transistor.

In an example implementation, the first transistor is an NMOS transistor, and the protection transistor is the NMOS transistor.

In an example implementation, the power supply branch is further configured to provide the first voltage to the word line prior to the first time.

In an example implementation, the power supply branch comprises a first voltage generator and a second switching unit. The first voltage generator is configured to provide a first voltage; the second switching unit is coupled between the first voltage generator and the word line, and is configured to, in response to a controlled end of the second switching unit receiving a first enable signal, be in the on state before the first time and in the off state after the first time.

In an example implementation, the second switching unit includes a second transistor, wherein a first electrode of the second transistor is coupled with the first voltage generator, a second electrode of the second transistor is coupled with the word line, and a control end of the second transistor is configured to receive the first enable signal.

In an example implementation, the power supply branch further comprises a second voltage generator and a third switching unit. The second voltage generator is configured to provide a second voltage; the third switching unit is coupled between the second voltage generator and the word line, and is configured to: in response to a controlled end of the third switching unit receiving the second enable signal, be in the off state before the second time and in the on state after the second time.

In an example implementation, the second switching unit includes a third transistor, wherein a first electrode of the third transistor is coupled with the second voltage generator, a second electrode of the third transistor is coupled with the word line, and a control end of the third transistor is configured to receive the second enable signal.

In an example implementation, the control circuit further includes a NOR gate, wherein an input end of the NOR gate is configured to receive the first enable signal and the second enable signal, and an output end of the NOR gate is coupled with the control end of the first transistor, and is configured to output the first control signal.

In an example implementation, the control circuit further includes a fourth switching unit coupled between the word line and the clamping unit, and configured to: in response to a controlled end of the fourth switching unit receiving the second control signal, be in the on state from the first time to the second time.

In an example implementation, the first voltage is a program voltage, the second voltage is a read voltage, and the program voltage is greater than the read voltage.

According to a second aspect, some examples of the present disclosure provide a memory including an array of memory cells and a peripheral circuit. The array of memory cells includes memory cells and a word line coupled with the memory cells. The peripheral circuit is coupled with the array of memory cells and includes the control circuit mentioned in any of the above implementations.

In an example implementation, the memory is a dynamic random access memory.

According to a third aspect, some examples of the present disclosure provide a memory system. The memory system includes the memory and the controller mentioned in any of the above implementations. The controller is coupled with the memory and configured to control the memory to store data.

According to a fourth aspect, some examples of the present disclosure provide a control method of a memory. The memory comprises a discharging end, a clamping unit, a first switching unit and a power supply branch, wherein the clamping unit is coupled with a word line of the memory, the first switching unit is coupled between the clamping unit and the discharging end, the power supply branch is coupled with the word line; the control method of the memory comprises: controlling the first switching unit to be in an on state from the first time to the second time, so that the word line is connected with the discharging end, and the voltage of the word line is discharged from the first voltage to the target voltage; and controlling the power supply branch to provide a second voltage to the word line after the second time, wherein the target voltage is less than or equal to the second voltage.

In an example implementation, controlling the first switching unit to be in the on state from the first time to the second time includes: in response to a controlled end of the first switching unit receiving the first control signal, the first switching unit being in the on state from the first time to the second time; wherein the control method further comprises: in response to the controlled end of the first switching unit receiving the first control signal, the first switching unit being in an off state before the first time and after the second time.

In an example implementation, the control method further comprises: controlling the power supply branch to provide the first voltage to the word line before the first time.

According to a fifth aspect, some examples of the present disclosure provide a discharge circuit of a memory. The discharge circuit of the memory comprises a discharging end, a diode-connected NMOS transistor and a first switching unit. The diode-connected NMOS transistor is coupled with the word line of the memory; the first switching unit is coupled between the diode-connected MOS transistor and the discharging end, and is configured to be in the on state from the first time to the second time, so that the word line is connected with the discharging end, and the voltage of the word line is discharged from the first voltage to the target voltage.

In an example implementation, a drain of the diode-connected NMOS transistor is coupled with a gate of the diode-connected NMOS transistor.

In an example implementation, the target voltage is the sum of a voltage of the discharging end and a threshold voltage of the diode-connected NMOS transistor.

### BRIEF DESCRIPTION OF THE DRAWINGS

Other features, objects and advantages of the present disclosure will become more apparent upon reading the detailed description of non-limiting examples made with reference to the following drawings, in which:

FIG. 1 is a schematic circuit diagram of a memory provided by an example of the present disclosure;

FIG. 2 is a schematic circuit diagram of a memory cell provided by an example of the present disclosure;

FIG. 3 is a schematic circuit diagram of a control circuit of a memory provided by an example of the present disclosure;

FIG. 4 is a waveform diagram of a control circuit of a memory during operation provided by an example of the present disclosure;

FIGS. 5A to FIG. 5C are schematic circuit diagrams of a clamping unit provided by an example of the present disclosure;

FIG. 6 is a schematic block diagram of a system having a memory system provided by an example of the present disclosure;

FIG. 7 is a schematic flow diagram of a control method of a memory provided by an example of the present disclosure; and

FIG. 8 is a schematic circuit diagram of a discharge circuit of a memory provided by an example of the present disclosure.

### DETAILED DESCRIPTION

In order to better understand the present disclosure, various aspects of the present disclosure will be described in more detail with reference to the accompanying drawings. It should be understood that these detailed descriptions are merely descriptions of example implementations of the present disclosure, and are not intended to limit the scope of the present disclosure in any manner. Throughout the description, like reference numbers refer to like elements. The expression “and/or” includes any and all combinations of one or more of the associated listed items.

It should be noted that in this specification, the expressions of the first, second, third, etc., are merely used for distinguishing one feature from another feature, and do not represent any limitation on the feature, and in particular, do not represent any order.

It should also be understood that expressions such as “including”, “included”, “having”, “comprising” or “comprised,” and the like, are open and not closed expressions in this specification that indicate the presence of at least one of stated features, elements, or components, but do not preclude the presence of one or more of other features, elements, components, and/or combinations thereof. Furthermore, when expressions such as “at least one of ...” appear after the list of listed features, it modifies the entire column of features rather than just modifying individual elements in the list. In addition, when describing the implementations of the present disclosure, using the word “may” mean “one or more implementations of the present disclosure”. Also, the term “example” is intended to refer to an example or illustration.

Unless otherwise defined, all wording (including engineering terms and scientific terms) used herein have the same meaning as commonly understood by those of ordinary skill in the art to which the present disclosure belongs. It should also be understood that unless explicitly stated in the present disclosure, words defined in a common dictionary should be interpreted as having a meaning that is consistent with their meaning in the context of the related art, and should not be interpreted in an idealized or overly formal sense.

It should be noted that, in the case of no conflict, the features in the implementations and implementations of the present disclosure may be combined with each other. In addition, unless expressly defined or contradicted with context, the operations included in the methods described in the present disclosure need not be limited to the recited order, but may be performed in any order or in parallel.

Furthermore, direct or indirect contact between the respective components may be represented in the present disclosure when “connected” or “coupled” is used, unless otherwise defined or otherwise derivable from the context.

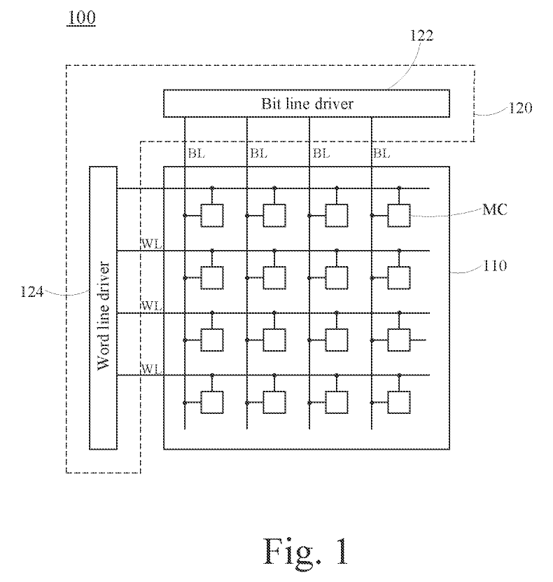

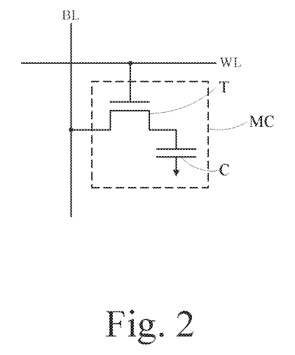

FIG. 1 is a schematic circuit diagram of a memory provided by an example of the present disclosure. FIG. 2 is a schematic circuit diagram of a memory cell provided by an example of the present disclosure.

As shown in FIG. 1 and FIG. 2, the memory 100 may include an array of memory cells 110 and a peripheral circuit 120 coupled with the array of memory cells 110. The array of memory cells 110 may include a plurality of memory cells MC. The plurality of memory cells MC may be arranged in a two-dimensional array having rows and columns. For example, the memory cells MC may be implemented as a dynamic random access memory (DRAM) type of memory cells, and the memory 100 may be referred to as the dynamic random access memory. As such, the memory cell MC may include a transistor T and a capacitor C coupled in series. For example, one of the source or the drain of the transistor T is coupled with the first electrode of the capacitor C, and the second electrode of the capacitor C is coupled with the ground. The capacitor C may implement binary information storage based on the stored different charges. Transistor T may act as a switch to access the binary information stored by capacitor C.

It should be noted that the memory cells MC may also be implemented as any suitable type of memory cells such as a Phase Change Memory (PCM), a Resistive Random Access Memory (RRAM), a Ferroelectric Random Access Memory (FRAM), or the like. Each of the above types of memory cells may include a memory node and a transistor for accessing binary information stored by the memory node. For example, for a PCM type of memory cell, the memory node may be an element of a chalcogenide material, and may enable binary information storage based on reversible transition between the amorphous state and the polycrystalline state induced by the current. For example, for a RRAM type of memory cell, the memory node may be an element of a metal-oxide material, and may enable binary information storage based on a change in the state of the conductive material caused by the current. For example, for a FRAM type of memory cell, the memory node may be an element of a ferroelectric material, and may enable binary information storage based on switching the ferroelectric material between two polarization states under external electric field conditions.

The array of memory cells 110 may also include a word line WL and a bit line BL. The word line WL may be used for coupling a row of memory cells MC and a peripheral circuit 120 (e.g., a word line driver 124). The bit line BL may be used for coupling a column of memory cells MC and the peripheral circuit 120 (e.g., a bit line driver 122). In the case where the memory cell MC is implemented as the DRAM type of memory cell, each word line WL may be coupled with the gate of the transistor T in the memory cell MC of the corresponding row. Each bit line BL may be coupled with one of the drain or the source of the transistor T in the memory cell MC of the corresponding column.

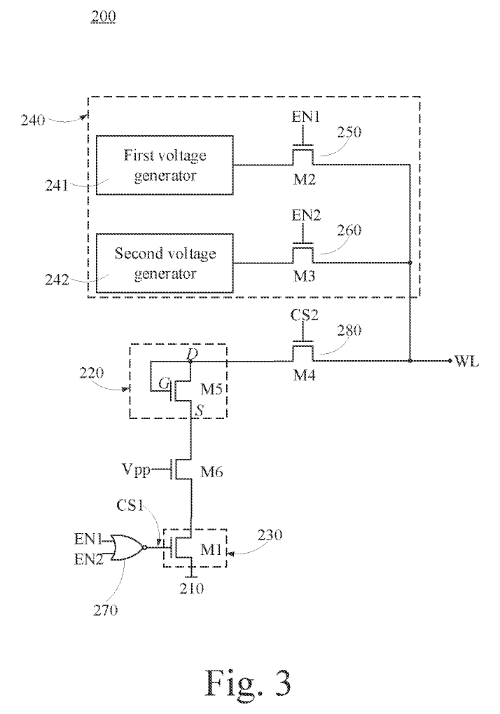

In some implementations, the peripheral circuit 120 may include at least one of digital, analog, or mixed-signal circuits to support the functionality of the array of memory cells 110. For example, the peripheral circuit 120 may include a bit line driver 122, a word line driver 124, a control circuit 200 (see FIG. 3), and other functional circuits composed of at least one of an active or a passive semiconductor device.

The program and read operation principles of the memory 100 are described below by taking the memory 100 as a DRAM memory, for example, the memory cell MC is implemented as the DRAM type of memory cell.

In some implementations, the memory cell MC relies on the presence or absence of stored charge in the capacitor C to distinguish between two states, indicating that the information “1” or “0” is stored. For example, if no charge is stored in the capacitor C, it means that the capacitor C stores data logic “0”; if there is a charge in the capacitor C, it means that the capacitor C stores data logic “1”.

When the memory 100 operates in the normal operation mode, for a program operation, first, a program voltage may be provided to the corresponding word line WL based on the row address, so that the transistor T of the memory cell MC of the target row is turned on. Next, the charge on the corresponding bit line BL may be caused to flow into the capacitor C of the memory cell MC located in the target column and the above target row coupled with the bit line BL based on the column address, thereby programming the original data logic “0” of the capacitor C to the data logic “1”; or the charge in the capacitor C located in the target column and the above target row may be caused to flow to the corresponding bit line BL based on the column address, thereby programming the original data logic “1” of the capacitor C to the data logic “0”. For a read operation, first, the corresponding bit line BL may be precharged based on the column address. Then, a read voltage may be provided to the corresponding word line WL based on the row address to turn on the transistor T of the memory cell MC of the target row, so that the capacitor C shares the charge with the above bit line BL. The data stored in the capacitor C is read as a logic “0” or a logic “1” by determining whether the voltage of the bit line BL rises or falls.

When the memory 100 operates in a one-time programmable (OTP) operating mode, the program voltage provided to the respective word line WL during the program operation is greater than the read voltage provided to the respective word line WL during the read operation. The voltages required for word line WL are provided by different voltage generators during the continuous execution of program operations and read operations. After performing the program operation, the program voltage with a larger voltage value needs to be discharged to meet the requirement of the voltage value required by the word line WL in the subsequent read operation. If the target voltage reached by the program voltage discharge is large, under the condition that the pull-down capability of the circuit for providing the read voltage is weak, it is difficult to quickly meet the requirement of the read voltage required by the word line WL, thereby affecting the accuracy of the subsequent read operation.

In view of this, the present disclosure provides a control circuit for a memory. The first voltage (e.g., program voltage) is discharged to the target voltage from the first time to the second time through the control of the first switching unit, such that the target voltage is less than or equal to the second voltage (for example, the read voltage) required by the word line after the second time. Based on the characteristic of the strong pull-up capability of the circuit for providing the second voltage, after the second voltage is provided to the word line, the voltage on the word line can quickly reach the second voltage from the target voltage, thereby achieving the voltage requirement required by the word line in the read operation, and further improving the accuracy of the read operation. In addition, the clamping unit can clamp the voltage on the word line to the target voltage during the discharging, so that the voltage on the word line is not too small, which helps the voltage on the word line to quickly reach the second voltage from the target voltage.

Hereinafter, the present disclosure will be described in detail with reference to the accompanying drawings and in combination with the examples.

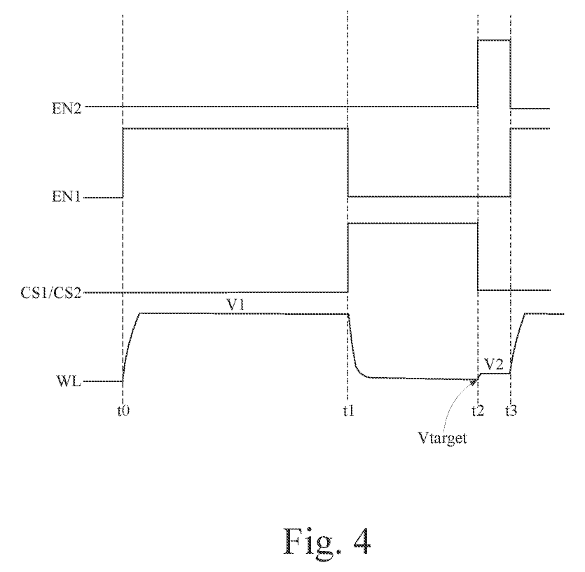

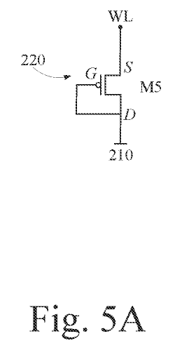

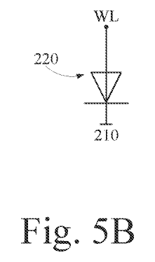

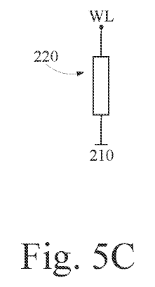

FIG. 3 is a schematic circuit diagram of a control circuit of a memory provided by an example of the present disclosure. FIG. 4 is a waveform diagram of a control circuit of a memory provided by an example of the present disclosure during operation. FIG. 5A to FIG. 5C are schematic circuit diagrams of a clamping unit provided by an example of the present disclosure. For example, a control circuit 200 (hereinafter referred to as control circuit 200) of the memory may be a part of the peripheral circuit 120 shown in FIG. 1.

As shown in FIG. 3 and FIG. 4, the control circuit 200 may include a discharging end 210, a clamping unit 220, a first switching unit 230, and a power supply branch 240. The clamping unit 220 is coupled with the word line WL. The first switching unit 230 is coupled between the clamping unit 220 and the discharging end 210 and is configured to be in the on state from the first time t1 to the second time t2, so that the word line WL is connected with the discharging end 210, and the voltage of the word line WL is discharged from the first voltage V1 to the target voltage Vtarget. The power supply branch 240 is coupled with the word line WL and is configured to provide the second voltage V2 to the word line WL after the second time t2, wherein the target voltage Vtarget is less than the second voltage V2. For example, the first voltage V1 may be the program voltage required to program the operated word line WL in the OTP operation mode. The second voltage V2 may be the read voltage required to read the operated word line WL in the OTP operation mode. The program voltage may be greater than the read voltage. For example, the program voltage may be about 6.5V, and the read voltage may be about 2V.

It should be noted that the voltage Vdischarge of the discharging end 210 may be less than the first voltage V1, and may be provided by any appropriate voltage source. In addition, FIG. 4 shows an example where the target voltage Vtarget is less than the second voltage V2. In other examples, the target voltage Vtarget may be equal to the second voltage V2.

In the control circuit 200 of the memory provided by the present disclosure, the first voltage V1 (e.g., the program voltage) is discharged to the target voltage Vtarget from the first time t1 to the second time t2 through the control of the first switching unit 230, such that the target voltage Vtarget is less than or equal to the second voltage V2 (for example, the read voltage) required by the word line WL after the second time t2. Based on the characteristic of the strong pull-up capability of the circuit for providing the second voltage, after the second voltage V2 is provided to the word line WL, the voltage on the word line WL can quickly reach the second voltage V2 from the target voltage Vtarget, thereby achieving the voltage requirement required by the word line WL in the read operation, and further improving the accuracy of the read operation. In addition, the clamping unit 220 can clamp the voltage on the word line WL at the target voltage Vtarget during the discharging, so that the voltage on the word line WL is not too small, which helps the voltage on the word line WL to quickly reach the second voltage V2 from the target voltage Vtarget.

In some implementations, the clamping unit 220 may include a diode-connected MOS transistor M5. The drain D of the diode-connected MOS transistor M5 is coupled with the gate G of the diode-connected MOS transistor M5. In this way, the potentials of the drain and the gate of the diode-connected MOS transistor are the same, and the MOS transistor can work in the saturation region and can serve as a load.

In some implementations, as shown in FIG. 3 and FIG. 5A, the diode-connected MOS transistor M5 may be an NMOS transistor or a PMOS transistor. In some examples, as shown in FIG. 3, in the case where the diode-connected MOS transistor M5 is an NMOS transistor, the drain D and the gate G of the diode-connected MOS transistor M5 may be coupled with the word line WL, and the source S of the diode-connected MOS transistor M5 may be coupled with the discharging end 210. When the NMOS transistor is selected for the diode-connected MOS transistor M5, the NMOS transistor has the characteristics of high electron mobility, fast switching speed, and small conduction loss, which helps to improve the discharge speed without extra area overhead. In other examples, as shown in FIG. 5A, in the case where the diode-connected MOS transistor M5 is a PMOS transistor, the drain D and the gate G of the diode-connected MOS transistor M5 may be coupled with the discharging end 210, and the source S of the diode-connected MOS transistor M5 may be coupled with the word line WL. In this implementation, when the diode-connected MOS transistor M5 is selected for the clamping unit 220, the CMOS process may be compatible, and the structure is simple.

In other implementations, as shown in FIG. 5B, the clamping unit 220 may further include a diode. For example, the anode of the diode is coupled with the word line WL, and the cathode of the diode is coupled with the discharging end 210. In still other implementations, as shown in FIG. 5C, the clamping unit 220 may further include a resistor. Two ends of the resistor are coupled between the word line WL and the discharging end 210. In this implementation, both the diode and the resistor may serve as a load. In some implementations, in the case where the diode-connected MOS transistor M5 may be an NMOS transistor or a PMOS transistor, the voltage Vdischarge of the discharging end 210 is less than or equal to a difference between the second voltage V2 and the threshold voltage Vth5 of the diode-connected MOS transistor M5. For example, the voltage Vdischarge of the discharging end 210, the second voltage V2 and the threshold voltage Vth5 of the diode-connected MOS transistor M5 may satisfy: Vdischarge - V2 ≤ Vth5. The threshold voltage Vth5 of the diode-connected MOS transistor M5 depends on parameters such as a physical structure and a material thereof, and the second voltage V2 may be a preset voltage value. For example, the voltage of the discharging end 210 is about 1.05V. By reasonably setting the voltage Vdischarge of the discharging end 210, the voltage on the word line WL can be clamped at the target voltage Vtarget during the discharging, so that the voltage on the word line WL is not too small, which helps the voltage on the word line WL to quickly reach the second voltage V2 from the target voltage Vtarget.

In some implementations, as shown in FIG. 3 and FIG. 4, the first switching unit 230 is further configured to, in response to the controlled end of the first switching unit 230 receiving the first control signal CS1, be in an on state from the first time t1 to the second time t2, and be in an off state before the first time t1 and after the second time t2. For example, the first control signal CS1 may be a low-level signal before the first time t1 and after the second time t2, and may be a high-level signal between the first time t1 and the second time t2. When the first control signal CS1 is a high level signal, the first control signal CS1 is valid.

In some implementations, the first switching unit 230 may include a first transistor M1. A first electrode of the first transistor M1 is coupled with the clamping unit 220, a second electrode of the first transistor M1 is coupled with the discharging end 210, and a control end of the first transistor M1 is configured to receive the first control signal CS1. In the case where the clamping unit 220 is a diode-connected NMOS transistor M5, the first electrode of the first transistor M1 is coupled with the source of the diode-connected NMOS transistor M5.

In some implementations, the first transistor M1 may be an NMOS transistor. For example, after the first time t1 and the second time t2, the control end of the first transistor M1 receives the first control signal CS1 at the low level, so that the first transistor M1 is in the turn-off state. Between the first time t1 and the second time t2, the first transistor M1 receives the first control signal CS1 at a high level, so that the first transistor M1 is in the turn-on state.

It should be noted that the first electrode of the first transistor M1 may be the source of the first transistor M1, and the second electrode of the first transistor M1 may be the drain of the first transistor M1. The first electrode of the first transistor M1 may also be the drain electrode of the first transistor M1, and the second electrode of the first transistor M1 may also be the source electrode of the first transistor M1. The source and the drain of the first transistor M1 are interchangeable.

In some implementations, as shown in FIG. 3, the control circuit 200 may further include a protection transistor M6. The protection transistor M6 may be coupled between the clamping unit 220 and the first transistor M1, and the protection transistor M6 performs overvoltage protection on the first transistor M1. In a case where the clamping unit 220 is a diode-connected NMOS transistor M5, the protection transistor M6 is coupled between the source of the diode-connected NMOS transistor M5 and the first electrode of the first transistor M1. As an example, the protection transistor M6 may be an NMOS transistor.

In some implementations, during the discharging, the control end of the protection transistor M6 is configured to receive the bias voltage Vpp, so that the protection transistor M6 is in the turn-on state.

In some implementations, as shown in FIGS. 3 and 4, the power supply branch 240 is further configured to provide the first voltage V1 to the word line WL before the first time t1. For example, the power supply branch 240 provides the first voltage V1 to the word line WL from the zeroth time t0 to the first time t1, so that the voltage on the word line WL is raised to the first voltage V1.

In some implementations, as shown in FIG. 3 and FIG. 4, the power supply branch 240 may include a first voltage generator 241 and a second switching unit 250. The first voltage generator 241 may be configured to provide a first voltage V1. The second switching unit 250 is coupled between the first voltage generator 241 and the word line WL, and is configured to: in response to the controlled end of the second switching unit 250 receiving the first enable signal EN1, be in the on state before the first time t1, and be in the off state after the first time t1. For example, the first enable signal EN1 is a different level signal before and after the first time t1. In an example, the first enable signal EN1 may be a high level signal before the first time t1, and may be a low level signal after the first time t1. When the first enable signal EN1 is the high level signal, the first enable signal EN1 is valid.

In some implementations, the second switching unit 250 may include a second transistor M2. A first electrode of the second transistor M2 is coupled with the first voltage generator 241, a second electrode of the second transistor M2 is coupled with the word line WL, and a control end of the second transistor M2 is configured to receive the first enable signal EN1. For example, before the first time t1, the control end of the second transistor M2 receives the first enable signal EN1 at a high level, so that the second transistor M2 is in the turn-on state. After the first time t1, the second transistor M2 receives the first enable signal EN1 at a low level, so that the second transistor M2 is in the turn-off state.

It should be noted that the first electrode of the second transistor M2 may be the source of the second transistor M2, and the second electrode of the second transistor M2 may be the drain of the second transistor M2. The first electrode of the second transistor M2 may also be the drain electrode of the second transistor M2, and the second electrode of the second transistor M2 may also be the source electrode of the second transistor M2. The source and the drain of the second transistor M2 are interchangeable.

In some implementations, as shown in FIG. 3 and FIG. 4, the power supply branch 240 also include a second voltage generator 242 and a third switching unit 260. The second voltage generator 242 may be configured to provide a second voltage V2. The third switching unit 260 may be coupled between the second voltage generator 242 and the word line WL, and may be configured to: in response to the controlled end of the third switching unit 260 receiving the second enable signal EN2, be in the off state before the second time t2, and be in the on state after the second time t2. For example, the second enable signal EN2 may be a different level signal before and after the second time t2. In an example, the second enable signal EN2 is a low level signal before the second time t2, and the second enable signal EN2 is a high level signal after the second time t2. When the second enable signal EN2 is a high level signal, the second enable signal EN2 is valid.

In some implementations, the third switching unit 260 includes a third transistor M3. A first electrode of the third transistor M3 is coupled with the second voltage generator 242, a second electrode of the third transistor M3 is coupled with the word line WL, and a control end of the third transistor M3 is configured to receive the second enable signal EN2. For example, before the second time t2, the control end of the third transistor M3 receives the second enable signal EN2 at a low level, so that the third transistor M3 is in the turn-off state. After the second time t2, the third transistor M3 receives the second enable signal EN2 at a high level, so that the third transistor M3 is in the turn-on state.

It should be noted that the first electrode of the third transistor M3 may be the source of the third transistor M3, and the second electrode of the third transistor M3 may be the drain of the third transistor M3. The first electrode of the third transistor M3 may also be the drain electrode of the third transistor M3, and the second electrode of the third transistor M3 may also be the source electrode of the third transistor M3. The source and the drain of the third transistor M3 are interchangeable.

In some implementations, as shown in FIG. 3, the control circuit 200 may further include a NOR gate 270. An input end of the NOR gate 270 is configured to receive the first enable signal EN1 and the second enable signal EN2, an output end of the NOR gate 270 is coupled with the control end of the first transistor M1, and may be configured to output the first control signal CS1. The NOR gate 270 may be configured to implement logical NOR function. In an example, when both input ends of the NOR gate 270 are input with low level signals, the output end of the NOR gate 270 outputs a high level signal. When one or more of the input ends of NOR gate 270 are input with high level signals, the output end of the NOR gate 270 outputs a low level signal. In this way, before the first time t1, the first enable signal EN1 is a high level signal, the second enable signal EN2 is a low level signal, and the first control signal CS1 output via the NOR gate 270 is a low level signal. From the first time t1 to the second time t2, the first enable signal EN1 and the second enable signal EN2 are both low level signals, and the first control signal CS1 output via the NOR gate 270 is a high level signal. After the second time t2, the first enable signal EN1 is a low level signal, the second enable signal EN2 is a high level signal, and the first control signal CS1 output via the NOR gate 270 is a low level signal.

In the above implementations, when the first enable signal EN1 and the second enable signal EN2 are both low level signals, the first voltage generator 241 and the second voltage generator 242 are not connected to the word line WL. At this time, the first control signal CS1 gated by the first enable signal EN1 and the second enable signal EN2 may connect the word line WL with the discharging end 210 through the first switching unit 230 (for example, the first transistor M1), so as to prevent the word line WL from being connected to the first voltage generator 241, the second voltage generator 242 and the discharging end 210 at the same time, thereby facilitating improve the reliability of the control circuit 200.

In some implementations, the control circuit 200 may further include a fourth switching unit 280. The fourth switching unit 280 may be coupled between the WL word line and the clamping unit 220, and may be configured to: in response to the controlled end of the fourth switching unit 280 receiving the second control signal CS2, be in the on state from the first time t1 to the second time t2. In an example, the fourth switching unit 280 may be further configured to: in response to the controlled end of the fourth switching unit 280 receiving the second control signal CS2, be in the off state before the first time t1 and after the second time t2.

In some implementations, the fourth switching unit 280 may include a fourth transistor M4. A first electrode of the fourth transistor M4 is coupled with the clamping unit 220, a second electrode of the fourth transistor M4 is coupled with the word line WL, and a control end of the fourth transistor M4 is configured to receive the second control signal CS2. For example, before the first time t1, the control end of the fourth transistor M4 receives the second control signal CS2 at a low level, so that the fourth transistor M4 is in the turn-off state. During the first time t1 to the second time t2, the control end of the fourth transistor M4 receives the second control signal CS2 at a high level, so that the fourth transistor M4 is in the turn-on state. After the second time t2, the fourth transistor M4 receives the second control signal CS2 at a low level, so that the fourth transistor M4 is in the turn-off state.

It should be noted that the first electrode of the fourth transistor M4 may be the source of the fourth transistor M4, and the second electrode of the fourth transistor M4 may be the drain of the fourth transistor M4. A first electrode of the fourth transistor M4 may also be a drain electrode of the fourth transistor M4, and a second electrode of the fourth transistor M4 may also be a source electrode of the fourth transistor M4. The source and the drain of the fourth transistor M4 are interchangeable.

In the above implementation, the fourth switching unit 280 (e.g., the fourth transistor M4) may be configured to control the word line WL and the discharging end 210 to be connected. On the basis of disposing the first switching unit 230, additionally disposing fourth switching unit 280 may increase the reliability of the control circuit 200.

The working process of the control circuit 200 will be described below with reference to FIG. 3 and FIG. 4.

The period from the zeroth time t0 to the first time t1 is a program operation period. In an example, the first enable signal EN1 is a high level signal, and the second transistor M2 is in the turn-on state. The word line WL is connected to the first voltage generator 241. The first voltage generator 241 provides a first voltage V1 to the word line WL. The second enable signal EN2 is a low level signal, and the third transistor M3 is in the turn-off state. The word line WL is not connected to the second voltage generator 242. The first enable signal EN1 at a high level and the second enable signal EN2 at a low level serve as the input signals of the NOR gate 270, and the output end of the NOR gate 270 outputs the first control signal CS1 at a low level. The first transistor M1 is in the turn-off state under the control of the first control signal CS1. Meanwhile, the second control signal CS2 is also a low-level signal. The fourth transistor M4 is also in the turn-off state under the control of the second control signal CS2. The word line WL is not connected to the discharging end 210.

The period from the first time t1 to the second time t2 is a discharging operation period. In an example, the first enable signal EN1 is a low level signal, and the second transistor M2 is in the turn-off state. The word line WL is not connected to the first voltage generator 241. The second enable signal EN2 is the low level signal, and the third transistor M3 is in the turn-off state. The word line WL is not connected to the second voltage generator 242. The first enable signal EN1 at the low level and the second enable signal EN2 at the low level serve as the input signals of the NOR gate 270, and the output end of the NOR gate 270 outputs the first control signal CS1 at a high level. The first transistor M1 is in the turn-on state under the control of the first control signal CS1. Meanwhile, the second control signal CS2 is also a high level signal. The fourth transistor M4 is in the turn-on under the control of the second control signal CS2. The word line WL is connected to the discharging end 210. The voltage of the word line WL decreases from the first voltage V1 until it reaches the target voltage Vtarget, and is clamped at the sum of the voltage Vdischarge at the discharging end 210 and the threshold voltage Vth5 of the fifth transistor M5.

The period from the second time t2 to the third time t3 is a reading operation period. In an example, the first enable signal EN1 is a low level signal, and the second transistor M2 is in the turn-off state. The word line WL is not connected to the first voltage generator 241. The second enable signal EN2 is a high level signal, and the third transistor M3 is in the turn-on state. The word line WL is connected to the second voltage generator 242. The second voltage generator 242 provides the second voltage V2 to the word line WL. When the target voltage is less than the second voltage V2, since the second voltage generator 242 has the characteristic of strong pull-up capability, the voltage of the word line WL quickly reaches the second voltage V2 from the target voltage Vtarget. When the target voltage is equal to the second voltage V2, under the action of the second voltage generator 242, the voltage of the word line WL is maintained at the target voltage Vtarget (e.g., the second voltage V2). The first enable signal EN1 at a low level and the second enable signal EN2 at a high level serve as the input signals of the NOR gate 270, and the output end of the NOR gate 270 outputs the first control signal CS1 at a low level. The first transistor M1 is in the turn-off state under the control of the first control signal CS1. Meanwhile, the second control signal CS2 is also the low level signal. The fourth transistor M4 is in the turn-off state under the control of the second control signal CS2. The word line WL is not connected to the ground end 210.

The example of the disclosure further provides a memory. As shown in FIGS. 1-4, the memory 100 may include an array of memory cells 110 and a peripheral circuit 120. The array of memory cells 110 may include memory cells MC and word lines WL. The peripheral circuit 120 is coupled with the array of memory cells 110, and the peripheral circuit 120 may include the control circuit 200 in any of the above implementations. Since the memory 100 includes the control circuit 200 in any of the above implementations of the present disclosure, the memory 100 may have the same beneficial effect as the control circuit 200, and details are not described herein again.

In some implementations, the memory 100 may be a DRAM memory. For example, a DRAM memory may include the DRAM type of a plurality of memory cells. For example, the memory 100 may operate in an OTP operation mode.

In other implementations, the memory 100 may also be one of a PCM memory, an RRAM memory, or a FRAM memory. For example, each of the above memories may include a PCM type of memory cells, an RRAM type of memory cells, and an FRAM type of memory cells, respectively.

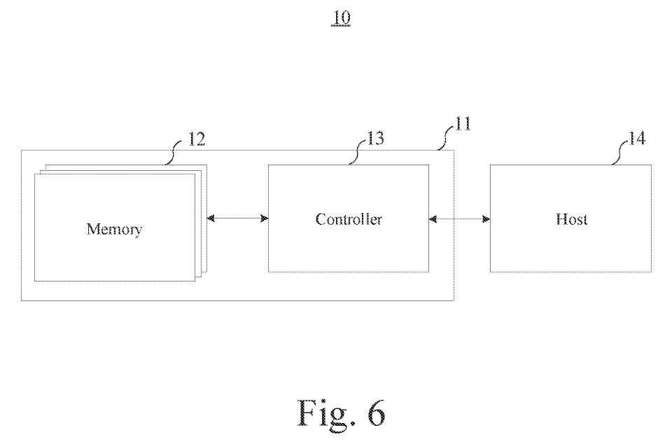

The example of the disclosure further provides a memory system. FIG. 6 is a schematic block diagram of a system having a memory system provided by an example of the present disclosure.

As shown in FIG. 6, the system 10 may be a mobile phone, a desktop computer, a laptop computer, a tablet, a vehicle computer, a gaming console, a printer, a positioning device, a wearable electronic device, a smart sensor, a virtual reality (VR) device, an augmented reality (AR) device, or any other suitable electronic device having a memory system 10 therein. As shown in FIG. 6, the system 10 may include a host 14 and a memory system 11 having one or more memories 12 and a controller 13. The host 14 may be a processor of an electronic device, such as a central processing unit (CPU), or a system-on-chip (SoC), such as an application processor (AP). The host 14 may be configured to send or receive data to or from the memory 12.

The memory 12 may include a memory (e.g., the memory 100) described in any of the implementations of the present disclosure, and according to some implementations, the controller 13 is coupled to the memory 12 and the host 14, and is configured to control the memory 12. The controller 13 may manage data stored in the memory 12 and communicate with the host 14. The controller 13 may be configured to control operations (such as read, erase, and program operations) of the memory 12. The controller 13 may communicate with an external device (e.g., host 14) according to a particular communication protocol.

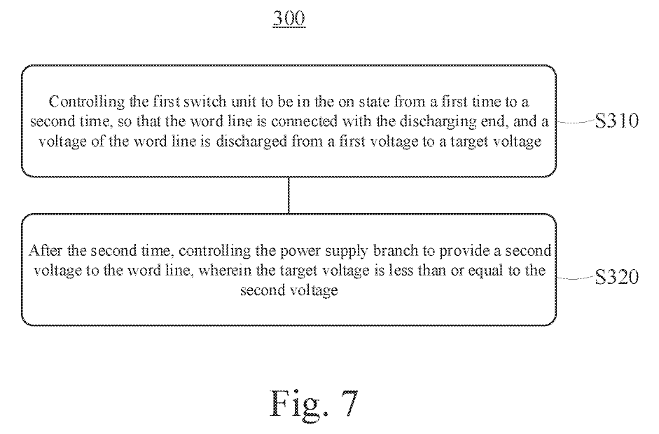

Some examples of the present disclosure further provide a control method of a memory. The memory may include a discharging end, a clamping unit, a first switching unit, and a power supply branch. The clamping unit is coupled with a word line of the memory, the first switching unit is coupled between the clamping unit and the discharging end, and the power supply branch is coupled with the word line. FIG. 7 is a schematic flow diagram of a control method of a memory provided by an example of the present disclosure. As shown in FIG. 7, the control method 300 of a memory (hereinafter referred to as control method 300) may include the following operations.

S310: controlling the first switching unit to be in the on state from a first time to a second time, so that the word line is connected with the discharging end, and a voltage of the word line is discharged from a first voltage to a target voltage.

S320, after the second time, controlling the power supply branch to provide a second voltage to the word line, wherein the target voltage is less than or equal to the second voltage.

According to the control method 300 provided by the example of the present disclosure, the first voltage (e.g., a program voltage) is discharged to the target voltage from the first time to the second time through the control of the first switching unit, such that the target voltage is less than or equal to the second voltage (for example, the read voltage) required by the word line after the second time. Based on the characteristic of the strong pull-up capability of the circuit for providing the second voltage, after the second voltage is provided to the word line, the voltage on the word line can quickly reach the second voltage from the target voltage, thereby achieving the voltage requirement required by the word line in the read operation, and further improving the accuracy of the read operation. In addition, the clamping unit can clamp the voltage on the word line at the target voltage during the discharging, so that the voltage on the word line is not too small, which helps the voltage on the word line to quickly reach the second voltage from the target voltage.

In some implementations, controlling the first switching unit to be in the on state from the first time to the second time, to connect the word line with the discharging end may include: in response to the controlled end of the first switching unit receiving the first control signal, the first switching unit being in the on state from the first time to the second time. In addition, the control method 300 may further include: in response to the controlled end of the first switching unit receiving the first control signal, the first switching unit is in the off state before the first time and after the second time. The processes of turning on and turning off the first switching unit have been described in detail in the section of the control circuit, which will not be repeated here.

In some implementations, the control method 300 may further include: controlling the power supply branch to provide the first voltage to the word line before the first time. The process of providing the voltage to the word line by the power supply circuit is described in detail in the section of the control circuit, which will not be repeated here.

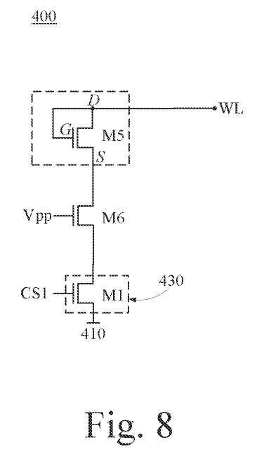

Some examples of the present disclosure further provide a discharge circuit of a memory. FIG. 8 is a schematic circuit diagram of a discharge circuit of a memory provided by an example of the present disclosure.

As shown in FIG. 8, the discharge circuit 400 (hereinafter referred to as discharge circuit 400) of the memory includes a discharging end 410, a diode-connected NMOS transistor M5, and a first switching unit 430. A diode-connected MOS transistor M5 is coupled with a word line WL of the memory. The first switching unit 430 is coupled between the diode-connected MOS transistor M5 and the discharging end 410, and is configured to be in the on state from the first time to the second time, so that the word line WL is connected with the discharging end 410, and a voltage of the word line WL is discharged from the first voltage to the target voltage.

It should be noted that the voltage of the discharging end 410 may be less than the first voltage, and may be provided by any appropriate voltage source.

According to the discharge circuit 400 provided by the example of the present disclosure, the voltage of the word line WL is controlled to be discharged from the first voltage to the target voltage through the first switching unit 430, and during the discharging, the diode-connected NMOS transistor M5 has the characteristics of high electron mobility, high switching speed and small conduction loss, which facilitates improving the discharging speed and does not add extra area overhead.

In some implementations, the drain of the diode-connected NMOS transistor M5 is coupled with the gate of the diode-connected NMOS transistor M5. In this way, the potentials of the drain and the gate of the diode-connected MOS transistor are the same, and the MOS transistor can work in the saturation region and can serve as a load.

In some implementations, the target voltage is the sum of a voltage of the discharging end and a threshold voltage of the diode-connected NMOS transistor. The threshold voltage of the diode-connected MOS transistor M5 depends on parameters such as a physical structure and a material thereof. The voltage of the discharging end can be set reasonably, so that the voltage of the word line WL is clamped at the target voltage during the discharging, and the target voltage can be flexibly adjusted.

In some implementations, the first switching unit 430 may include a first transistor M1. A first electrode of the first transistor M1 is coupled with the source of the diode-connected NMOS transistor M5, a second electrode of the first transistor M1 is coupled with the discharging end 410, and a control end of the first transistor M1 is configured to receive the first control signal CS1.

In some implementations, as shown in FIG. 8, the discharge circuit 400 may further include a protection transistor M6. The protection transistor M6 may be coupled between the diode-connected NMOS transistor M5 and the first transistor M1, and the protection transistor M6 performs overvoltage protection on the first transistor M1.

The above description is only the implementations of the present disclosure and an explanation of the applied technical principle. Those skilled in the art should understand that the protection scope involved in the present disclosure is not limited to the technical solutions of the combination of the technical features described above, and should also cover other technical solutions formed by any combination of the above technical features or their equivalent features without departing from the technical concept, for example, technical solutions formed by mutually replacing the above features with the technical features having similar functions as those disclosed in the present disclosure (but without limitation).

What is claimed is:

1. A control circuit of a memory, comprising:
a discharging end;
a clamping unit coupled with a word line of the memory;
a first switching unit coupled between the clamping unit and the discharging end and configured to be in an on state from a first time to a second time to connect the word line with the discharging end to discharge a voltage of the word line from a first voltage to a target voltage; and
a power supply branch coupled with the word line and configured to provide a second voltage to the word line after the second time,
wherein the target voltage is less than or equal to the second voltage.

2. The control circuit according to claim 1, wherein the clamping unit comprises a diode-connected metal oxide semiconductor (MOS) transistor, and wherein a drain of the diode-connected MOS transistor is coupled with a gate of the diode-connected MOS transistor.

3. The control circuit according to claim 2, wherein the diode-connected MOS transistor is an n-type MOS (NMOS) transistor or a p-type MOS (PMOS) transistor.

4. The control circuit according to claim 3, wherein a voltage of the discharging end is less than or equal to a difference between the second voltage and a threshold voltage of the diode-connected MOS transistor.

5. The control circuit according to claim 1, wherein the clamping unit comprises at least one of a diode or a resistor.

6. The control circuit according to claim 1, wherein the first switching unit is further configured to, in response to a controlled end of the first switching unit receiving a first control signal, be in the on state from the first time to the second time, and be in an off state before the first time and after the second time.

7. The control circuit according to claim 6, wherein the first switching unit comprises a first transistor, wherein a first electrode of the first transistor is coupled with the clamping unit, wherein a second electrode of the first transistor is coupled with the discharging end, and wherein a control end of the first transistor is configured to receive the first control signal.

8. The control circuit according to claim 7, wherein the control circuit further comprises a protection transistor coupled between the clamping unit and the first transistor, and wherein the protection transistor performs overvoltage protection on the first transistor.

9. The control circuit according to claim 8, wherein the first transistor is an n-type metal oxide semiconductor (NMOS) transistor, and wherein the protection transistor is the NMOS transistor.

10. The control circuit according to claim 7, wherein the power supply branch is further configured to provide the first voltage to the word line before the first time.

11. The control circuit according to claim 7, wherein the power supply branch comprises:
a first voltage generator configured to provide the first voltage; and
a second switching unit coupled between the first voltage generator and the word line and configured to, in response to a controlled end of the second switching unit receiving a first enable signal, be in the on state before the first time, and be in the off state after the first time.

12. The control circuit according to claim 11, wherein the second switching unit comprises a second transistor, wherein a first electrode of the second transistor is coupled with the first voltage generator, wherein a second electrode of the second transistor is coupled with the word line, and wherein a control end of the second transistor is configured to receive the first enable signal.

13. The control circuit according to claim 11, wherein the power supply branch further comprises:
a second voltage generator configured to provide the second voltage; and
a third switching unit coupled between the second voltage generator and the word line, and configured to, in response to a controlled end of the third switching unit receiving a second enable signal, be in the off state before the second time, and be in the on state after the second time.

14. The control circuit according to claim 13, wherein the second switching unit comprises a third transistor, wherein a first electrode of the third transistor is coupled with the second voltage generator, wherein a second electrode of the third transistor is coupled with the word line, and wherein a control end of the third transistor is configured to receive the second enable signal.

15. The control circuit according to claim 13, wherein the control circuit further comprises:
a NOR gate, wherein an input end of the NOR gate is configured to receive the first enable signal and the second enable signal, and wherein an output end of the NOR gate is coupled with the control end of the first transistor and is configured to output the first control signal.

16. The control circuit according to claim 1, wherein the control circuit further comprises a fourth switching unit coupled between the word line and the clamping unit and configured to, in response to a controlled end of the fourth switching unit receiving a second control signal, be in the on state from the first time to the second time.

17. The control circuit according to claim 1, wherein the first voltage is a program voltage, wherein the second voltage is a read voltage, and wherein the program voltage is greater than the read voltage.

18. A memory, comprising:
a memory array comprising memory cells and a word line coupled with the memory cells; and
a peripheral circuit coupled with the memory array and comprising a control circuit, the control circuit comprising:
a discharging end;
a clamping unit coupled with the word line;
a first switching unit coupled between the clamping unit and the discharging end and configured to be in an on state from a first time to a second time to connect the word line with the discharging end to discharge a voltage of the word line from a first voltage to a target voltage; and
a power supply branch coupled with the word line and configured to provide a second voltage to the word line after the second time,
wherein the target voltage is less than or equal to the second voltage.

19. The memory according to claim 18, wherein the memory is a dynamic random access memory.

20. A control method of a memory, wherein the memory comprises a discharging end, a clamping unit, a first switching unit and a power supply branch, wherein the clamping unit is coupled with a word line of the memory, wherein the first switching unit is coupled between the clamping unit and the discharging end, and wherein the power supply branch is coupled with the word line, the control method comprising:
controlling the first switching unit to be in an on state from a first time to a second time to connect the word line with the discharging end to discharge a voltage of the word line from a first voltage to a target voltage; and
controlling the power supply branch to provide a second voltage to the word line after the second time,
wherein the target voltage is less than or equal to the second voltage.
